(19) United States
(12) Patent Application Publication
(10) Pub. No.: US 2019/0169447 A1
(43) Pub. Date: Jun. 6, 2019

(54) SOLVENT AND METHOD OF FORMING ORGANIC FILM USING SOLVENT

(71) Applicant: FLOSFIA INC., Kyoto (JP)

(72) Inventors: Shigetaka KATORI, Okayama (JP); Takashi SHINOHE, Kyoto (JP); Takuto IGAWA, Kyoto (JP)

(21) Appl. No.: 16/206,067

(22) Filed: Nov. 30, 2018

(30) Foreign Application Priority Data
Dec. 1, 2017 (JP) 2017-232110

(51) Int. Cl. C09D 7/20; C09D 1/00; C09D 7/40; C09D 5/24; H01L 51/00; C23C 16/448; B05D 1/00

(52) U.S. Cl. CPC C09D 7/20; C09D 1/00; C09D 7/67; B82Y 30/00; H01L 51/0007; C23C 16/448; B05D 1/60; C09D 5/24

(57) ABSTRACT

In a first aspect of a present inventive subject matter, a solvent contains a nonpolar solvent containing an aromatic compound and a polar solvent that is an aprotic polar solvent. The ratio of the nonpolar solvent to the polar solvent by volume ratio is 5:1 to 1:1.

### CROSS-REFERENCE TO RELATED APPLICATION

This application is a new U.S. patent application that claims priority benefit of Japanese patent application No. 2017-232110 filed on Dec. 1, 2017, the disclosures of which are incorporated herein by reference in its entirety.

### BACKGROUND OF THE INVENTION

### Field of the Invention

The present disclosure relates to a solvent. Also, the present disclosure relates to a chemical composition. Furthermore, the present disclosure relates to a method of forming an organic film using the solvent.

### Description of the Related Art

It is open to the public that a semiconductor element, which is an organic semiconductor element having rectification properties and optical sensing properties, includes a thin film formed by use of fullerenes, especially at least one selected from among carbon cluster C60 and C70 as a semiconductor, and electrodes formed on the thin film. Also, it is suggested to form the thin film by a vacuum deposition method and a cast method as examples (For reference, see PL1: Japanese Unexamined Patent Application Publication No. JPH0629514A).

However, the vacuum deposition method requires a vacuum device and a high heating temperature that is higher than 500° C., for example, 520° C. to 550° C. suggested in PL1 during vacuum deposition. Also, if a film is formed by the cast method, residues of organic solvent, water, and/or oxygen due to the method may give undesirable influence on electrical properties of the film to be obtained.

Also, it is open to the public that a method of forming transparent conductive thin oxide films and organic polymer solar cells by a solution-based ultrasonic mist deposition method. This technique enabled low-resistive gallium-doped zinc oxide (ZnO:Ga) and indium-tin oxide (ITO) thin films capable of applying as anode layers in the device. Low resistive and flat PEDOS:PSS hole transport layer and P3HT:PCBM active layers were also deposited by this technique. The solar-cell devices with mist-deposited PEDOT:PSS or P3HT:PCBM layers were also deposited by this technique (For reference, see NPL1: Takumi IKENOUE and Shizuo FUJITA, “Solution-Based Ultrasonic Mist Deposition Method for the Formation of Transparent Conductive Thin Oxide Films and Organic Polymer Solar Cells).

NPL 1 discloses a mist deposition method to form films containing PCBM from a raw material solution containing PCBM as a fullerene derivative and chlorobenzene as a solvent, however, by use of the method disclosed by NPL 1, it is not possible to obtain a film of fullerene with characteristics of fullerene, because NPL1 uses fullerene derivative. Also, the solvent may be evaporated away from a base, which affects quality of the film to be formed on the base.

### SUMMARY OF THE INVENTION

In a first aspect of a present inventive subject matter, a solvent contains a nonpolar solvent containing an aromatic compound and a polar solvent that is an aprotic polar solvent. The ratio of the nonpolar solvent to the polar solvent by volume ratio is 5:1 to 1:1.

In a second aspect of a present inventive subject matter, a solvent contains a nonpolar solvent containing an aromatic compound and a polar solvent that is an aprotic polar solvent. The ratio of the nonpolar solvent to the polar solvent by volume ratio is 4:1 to 7:3.

It is disclosed that the aromatic compound contained in the nonpolar solvent is represented by the following Chemical Formula (1),

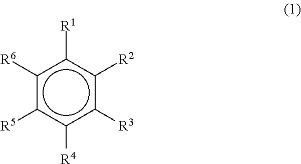

in the Chemical Formula (1), wherein

R¹, R², R³, R⁴, R⁵ and R⁶ each represent a hydrogen atom or an optionally substituted hydrocarbon group.

Also, it is suggested that two selected from among R¹, R², R³, R⁴, R⁵ and R⁶ may be taken together to form a ring.

According to an embodiment of a present inventive subject matter, the aprotic polar solvent is an amide solvent.

Also, it is suggested that the polar solvent has a boiling point that is higher than a boiling point of the nonpolar solvent by 50° C. or higher.

Furthermore, a chemical compound containing the solvent according to a present inventive subject matter and an organic compound is disclosed.

It is suggested that the organic compound is a cyclic compound.

Also, it is suggested that the organic compound is without a polar group.

It is disclosed that the organic compound has a solubility that is less than 1.0 mg/mL to the polar solvent at the temperature of 25° C.

In a third aspect of a present inventive subject matter, a method of forming an organic film includes preparing a raw material solution containing a solvent and an organic compound, the solvent containing a nonpolar solvent that contains an aromatic compound and a polar solvent that is an aprotic polar solvent; turning the raw material solution into atomized droplets; carrying the atomized droplets onto the base; and causing thermal reaction of the atomized droplets adjacent to the base to form on an organic film.

Also, it is suggested that the turning the raw material solution into atomized droplets is done by using ultrasonic vibration.

Furthermore, according to an embodiment of a present inventive subject matter, it is suggested that the base may include at least one layer.

### BRIEF DESCRIPTION OF THE DRAWING

FIG. 1 shows a schematic diagram of a mist chemical vapor deposition (CVD) apparatus that may be used as a film (layer)-formation apparatus according to an embodiment of a method of a present inventive subject matter.

FIG. 2 shows a UV-visible absorption measurement result of organic films obtained according to embodiments of a method of a present inventive subject matter.

FIG. 3 shows a measurement result of current voltage (I-V) characteristics of an organic film obtained according to an embodiment of a method of a present inventive subject matter.

### DETAILED DESCRIPTION OF EMBODIMENTS

The terminology used herein is for the purpose of describing particular embodiments only and is not intended to be limiting of the subject matter. As used herein, the singular forms “a”, “an” and “the” are intended to include the plural forms as well, unless the context clearly indicates otherwise.

As used herein, the term “and/or” includes any and all combinations of one or more of the associated listed items.

As illustrated in the figures submitted herewith, some sizes of structures or portions may be exaggerated relative to other structures or portions for illustrative purposes. Relative terms such as “below” or “above” or “upper” or “lower” may be used herein to describe a relationship of one element, layer or region to another element, layer or region as illustrated in the figures. It will be understood that these terms are intended to encompass different orientations of a layer, a device, and/or a system in addition to the orientation depicted in the figures.

Inventors of a present inventive subject matter suggest a solvent containing a nonpolar solvent that contains an aromatic compound and a polar solvent that is an aprotic polar solvent. The ratio of the nonpolar solvent to the polar solvent by volume ratio is 5:1 to 1:1. The solvent is able to be used to form an organic film in enhanced quality.

For example, according to embodiments of a method of a present inventive subject matter, it is possible to form a film of fullerene with characteristics of fullerene as an organic film. Films of fullerene are expected to be more suitably used as heat protection films compared to ordinary carbon films, since fullerene has the thermal conductivity much lower than the thermal conductivity of graphite. Also, films of fullerene are expected to be used as electrically-insulating films and black matrix with high resistance of color filters, since electrical conductivity of fullerene is very low. Furthermore, fullerene, which has suitable characteristics as an n-type semiconductor molecule, is also expected to be used for organic n-type semiconductor films.

The solvent according to a present inventive subject matter contains at least a nonpolar solvent and a polar solvent.

The nonpolar solvent is not particularly limited as long as the nonpolar solvent is nonpolar and contains an aromatic compound that is able to be used as a solvent. Also, the nonpolar solvent may be the aromatic compound. To form an organic film preferably, the aromatic compound contained in the nonpolar solvent is represented by the following Chemical Formula (1):

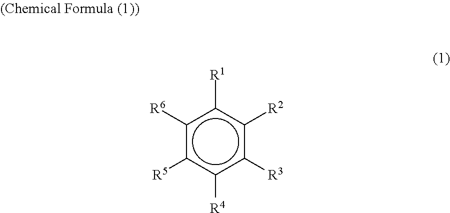

In the Chemical Formula (1), wherein R¹, R², R³, R⁴, R⁵ and R⁶ each represent a hydrogen atom or an optionally substituted hydrocarbon group.

In the Chemical Formula (1), R¹, R², R³, R⁴, R⁵ and R⁶ may be the same or different. For example, at least two of R¹, R², R³, R⁴, R⁵ and R⁶ may be the same. Also, at least one of R¹, R², R³, R⁴, R⁵ and R⁶ may be different from others. Furthermore, Also, R¹, R², R³, R⁴, R⁵ and R⁶ may be different from one another.

Also, two selected from among R¹, R², R³, R⁴, R⁵ and R⁶ may be taken together to form a ring.

According to embodiments of a present inventive subject matter, the aromatic compound is preferably an alkyl aromatic compound. The alkyl aromatic compound is not particularly limited as long as the alkyl aromatic compound is an aromatic compound with at least one alkyl group.

The alkyl group is preferably a linear alkyl group having 1 to 20 carbon atom(s), a branched alkyl group having 1 to 20 carbon atom(s), or a cyclic alkyl group having 1 to 20 carbon atom(s). Specific examples of the alkyl group include methyl, ethyl, n-propyl, 2-propyl, n-butyl, 1-methylpropyl, 2-methylpropyl, tert-butyl, n-pentyl, 1-methylbutyl, 1-Ethylpropyl, tert-pentyl, 2-methylbutyl, 3-methylbutyl, 2,2-dimethylpropyl, n-hexyl, 1-methylpentyl, 1-ethylbutyl, 2-methylpentyl, 3-methylpentyl, 4-methylpentyl, 2-methyl pentane, 2-methylpentan-3-yl, 3,3-dimethylbutyl, 2,2-dimethylbutyl, 1,1-dimethylbutyl, 1,2-dimethylbutyl, 1,3-dimethylbutyl, 2,3-dimethylbutyl, 1-ethylbutyl, 2-ethylbutyl, heptyl, octyl, nonyl, decyl, undecyl, dodecyl, tridecyl, tetradecyl, pentadecyl, hexadecyl, heptadecyl, octadecyl, nonadecyl, eicosyl, cyclopropyl, cyclobutyl, cyclopentyl and cyclohexyl. The alkyl group is preferably an alkyl group having 1 to 10 carbon atom(s), still further preferably an alkyl group having 1 to 6 carbon atom(s), and particularly preferably an alkyl group having 1 to 4 carbon atom(s), according to embodiments of a present inventive subject matter.

Examples of the “hydrocarbon group” include an alkyl group, an aryl group, and an aralkyl group.

Examples of the alkyl group are mentioned as above.

The aryl group is preferably an aryl group having 6 to 20 carbon atoms. Specific examples of the aryl group include phenyl, indenyl, pentalenyl, naphthyl, azulenyl, fluorenyl, phenanthrenyl, anthracenyl, acenaphthylenyl, biphenylenyl, naphthacenyl and pyrenyl. Among them, an aryl group having 6 to 14 carbon atoms is further preferable, according to embodiments of a present inventive subject matter.

The aralkyl group is preferably an aralkyl group having 7 to 20 carbon atoms. Specific examples of the aralkyl group include benzyl, phenethyl, 1-phenylpropyl, 2-phenylpropyl, 3-phenylpropyl, 1-phenylbutyl, 2-phenylbutyl, 3-phenylbutyl, 4-phenylbutyl, 1-phenylpentylbutyl, 2-phenylpentylbutyl, 3-phenylpentylbutyl, 4-phenylpentylbutyl, 5-phenylpentylbutyl, 1-phenylhexylbutyl, 2-phenylhexylbutyl, 3-phenylhexylbutyl, 4-phenylhexylbutyl, 5-phenylhexylbutyl, 6-phenylhexylbutyl, 1-phenylheptyl, 1-phenyloctyl, 1-phenylnonyl, 1-phenyldecyl, 1-phenylundecyl, 1-phenyldodecyl, 1-phenyltridecyl and 1-phenyl-tetradecyl. Among them, the aralkyl group is further preferably an aralkyl group having 7 to 12 carbon atoms, according to embodiments of a present inventive subject matter.

As an embodiment of a present inventive subject matter, in the Chemical Formula (1), two selected from among R¹, R², R³, R⁴, R⁵ and R⁶ is preferably taken together to form a ring. Examples of the ring of the two selected from among R¹, R², R³, R⁴, R⁵ and R⁶ include rings of a 5-membered ring to a 20-membered ring. Preferable examples of the ring that is a monocyclic ring of the two selected from among R¹, R², R³, R⁴, R⁵ and R⁶ include a cyclopentane ring, a cyclohexane ring, a cycloheptane ring, a cyclooctane ring, a cyclodecane ring, a cyclododecane ring, a cyclotetradecane ring, a cyclopentadecane ring, a cyclohexadecane ring, and a cycloheptadecane ring. Also, preferable examples of the ring that is a fused ring of the two selected from among R¹, R², R³, R⁴, R⁵ and R⁶ include a dihydronaphthalene ring, an indene ring, and an indane ring. Furthermore, the above-mentioned ring may be substituted by a hydrocarbon group, for example. Examples of the “hydrocarbon group” are referred to the above-mentioned hydrocarbon groups.

Examples of the alkyl aromatic compound include toluene, xylene, trimethylbenzene, ethylbenzene, ethyl toluene, ethyl xylene, diethyl benzene, alkylbenzene including propyl benzene, methyl naphthalene, ethyl naphthalene, alkyl naphthalene, tetralin, alkyl biphenyl, and alkyl anthracene. According to embodiments of a present inventive subject matter, the alkyl aromatic compound is preferably trimethylbenzene. Examples of trimethylbenzene include 1,2,3-trimethylbenzene, 1,2,4-trimethylbenzene, and 1,3,5-trimethylbenzene. According to an embodiment of a present inventive subject matter, the alkyl aromatic compound is preferably 1,3,5-trimethylbenzene.

The polar solvent is not particularly limited as long as the polar solvent is an aprotic solvent and with difficulty to donate a proton.

Examples of the aprotic solvent include an amide solvent, a lactone-based solvent, a sulfoxide-based solvent, a nitrile-based solvent, an organic phosphorus solvent, and a cellosolve solvent. Examples of the amide solvent include N,N-dimethylacetamide, N-methylpyrrolidone, 2-pyrrolidone, N-methylcaprolactam, N,N-dimethylformamide, N,N-diethylformamide, N, N-diethylacetamide, N-methylpropionamide, and methyl imidazolidinone. Examples of the lactone-based solvent include β-lactones such as β-propiolactone and β-butyrolactone, γ-lactones such as γ-butyrolactone, γ-valerolactone, γ-caprolactone, γ-caprylolactone, γ-laurolactone, δ-lactones such as δ-valerolactone, and ε-lactones such as ε-caprolactone. Examples of the sulfoxide-based solvent include dimethyl sulfoxide, diethyl sulfoxide, methylphenyl sulfoxide, and tetramethylene sulfoxide. Examples of the nitrile-based solvent include benzonitrile, acetonitrile, propionitrile, butyronitrile, and adiponitrile. Examples of the organic phosphorus solvent include tetramethyl phosphoric triamide and hexamethylphosphoric amide. Examples of the cellosolve solvent include ethyl cellosolve acetate and methyl cellosolve acetate.

According to embodiments of a present inventive subject matter, the polar solvent is preferably an amide solvent, and further preferably 2-pyrrolidone.

Also, according to embodiments of a present inventive subject matter, the boiling point of the polar solvent is preferably higher than the boiling point of the nonpolar solvent to obtain an organic film with enhanced quality. The boiling point of the polar solvent is preferably higher than the boiling point of the nonpolar solvent by 50° C. or higher, and most preferably higher than the boiling point of the nonpolar solvent by 70° C. or higher. The term “boiling point” herein means a boiling point under atmospheric pressure. For more details, the boiling point of the nonpolar solvent is preferably in a range of 100° C. to 300° C., and further preferably in a range of 100° C. to 200° C., and most preferably in a range of 150° C. to 200° C. The boiling point of the polar solvent is preferably 150° C. or higher, and further preferably 200° C. or higher. The boiling point of the polar solvent is most preferably in a range of 200° C. to 300° C.

The ratio of the nonpolar solvent mixed in the solvent containing the nonpolar solvent and the polar solvent is not particularly limited, however, according to an embodiment of a present inventive subject matter, the ratio of the nonpolar solvent mixed in the solvent is preferably in a range of 0.01 mol % to 99 mol %, and further preferably in a range of 1 mol % to 50 mol %. Also, the volume ratio of the nonpolar solvent to the polar solvent may be 5:1 to 1:1, and preferably 5:1 to 2:1, and further preferably 4:1 to 7:3.

The solvent is not particularly limited as long as the solvent contains the nonpolar solvent and the polar solvent to be the above-mentioned volume ratio. Furthermore, the solvent may contain an additional solvent. The additional solvent is not particularly limited, and may be different from the polar solvent and the nonpolar solvent. The additional solvent may be an organic solvent. Examples of the organic solvent include an alcohol, an ester, and an ether. Also, the additional solvent may be an inorganic solvent such as water. For more details, examples of water include pure water, ultrapure water, tap water, well water, mineral spring water, mineral water, hot spring water, spring water, fresh water, and seawater.

Using the solvent as mentioned above, it is possible to form an organic film industrially advantageously. Specifically, it is possible to form an organic film with enhanced quality from a chemical composition as a raw material solution containing the solvent as mentioned above and an organic compound.

The organic compound is not particularly limited as long as an object of the present inventive subject matter is not interfered with, and may be a cyclic organic compound or an acyclic organic compound. However, according to embodiments of a present inventive subject matter, the organic compound is preferably a cyclic organic compound. Examples of the cyclic organic compound include a polycyclic organic compound and a monocyclic organic compound. Examples of the polycyclic organic compound include naphthalene, anthracene, phenanthrene, methylnaphthalene, ethylnaphthalene, naphthacene, pentacene, pyrene, picene, triphenylene, anthanthrene, acenaphthene, acenaphthylene, benzopyrene, benzofluorene, benzophenanthrene, benzofluoranthene, benzoperylene, coronene, chrysene, hexabenzoperylene, phthalocyanine, perylene, perinone, anthraquinone, quinacridone, quinacridonequinon, dioxazine, indigo, thioindigo, pyranthrone, anthanthrone, flavanthrone, indanthrone, isoindolinone, quinophthalone, and fullerene. Examples of the monocyclic organic compound include benzene, toluene, xylene, phenol, alkylphenol, resorcin, diphenyl, diphenyl ether, alkylbenzene and cumene. According to an embodiment of a present inventive subject matter, the organic compound may be a cyclic organic compound, and preferably an aromatic compound, and further preferably a polycyclic aromatic compound. The organic compound is most preferably a fullerene to form a film of fullerene according to embodiments of a present inventive subject matter. The fullerene may be chemically-modified fullerene, however, according to embodiments of a present inventive subject matter, the fullerene that is not chemically-modified fullerene is further preferable to form a film of fullerene. Examples of the fullerene include C36 fullerene, C60 fullerene, C70 fullerene, C76 fullerene, C78 fullerene, C82 fullerene, C84 fullerene, C90 fullerene, and C96 fullerene. According to an embodiment of a present inventive subject matter, the fullerene is preferably C60 fullerene.

Also, the organic compound may be with a polar group or without a polar group, however, according to a present inventive subject matter, the organic compound is preferably without a polar group. The polar group may be a polar functional group or a polar atomic group. Examples of the polar group include a hydroxy group, a cyano group, an alkoxy group, a carboxy group, an amino group, a carbonyl group, a nitro group, a thiol group, a sulfonyl group, a phosphonyl group, a halogen group, an ester group, an epoxy group, a group including a fluorine atom, a group including a sulfur atom, a group having a lactone skeleton, a group having an acetal structure, a group having an ester bond, and a group having an ether bond. According to an embodiment of a present inventive subject matter, organic films are able to be formed in enhanced quality even if the organic compound does not have a polar group.

The raw material(s) is not particularly limited as long as the raw material(s) contains the organic compound, and the raw materials may contain the organic compound and an additive. The additive is not particularly limited as long as an object of a present inventive subject matter is not interfered with, and may be a known additive. The mixing ratio of the additive in the raw materials is not particularly limited, however, preferably in a range of 0.00001 mol % to 30 mol %, and further preferably in a range of 0.0001 mol % to 10 mol %. According to embodiments of a present inventive subject matter, an organic compound may have a solubility that is less than 1.0 mg/mL to a polar solvent at the temperature of 25° C., and here the term “solubility” means a mass (mg) of the organic compound dissolved in the polar solvent that was 1.0 mL. According to a present inventive subject matter, the organic compound is added into the polar solvent that is 1.0 mL to saturation point, and the remaining organic compound in the polar solvent was measured by deducting the remaining amount of organic compound in the polar solvent from the total amount of added organic compound in the polar solvent. Using an organic compound having a low solubility that is less than 1.0 mg/mL in the polar solvent, it is possible to obtain a raw material solution to be more suitably turned into atomized droplets. Also, the organic compound has a solubility that is 1.0 mg/mL or more to the nonpolar solvent at the temperature of 25° C., and further preferably has a solubility that is 1.5 mg/mL or more to the nonpolar solvent at the temperature of 25° C., and here the term “solubility” means a mass (mg) of the organic compound dissolved in the nonpolar solvent that was 1.0 mL. According to a present inventive subject matter, the organic compound is added into the nonpolar solvent that is 1.0 mL to saturation point, and the remaining organic compound in the nonpolar solvent was measured by deducting the remaining amount of organic compound in the nonpolar solvent from the total amount of added organic compound in the nonpolar solvent.

The mixing ratio of the organic compound in the raw material solution is not particularly limited, however, preferably in a range of 0.001 weight % (wt %) to 80 wt %, and further preferably in a range of 0.01 wt % to 80 wt %.

The chemical composition to form an organic film may further contain an additive. The additive is not particularly limited as long as an object of a present inventive subject matter is not interfered with. The additive may be an acid, an alkali, and/or a solvent, and the additive may be a known additive. The additive may be an inorganic additive or may be an organic additive. Examples of the acid include hydrofluoric acid, hydrochloric acid, hydrobromic acid, hydroiodic acid, sulfuric acid, phosphoric acid, nitric acid, acetic acid, carbonate acid, formic acid, benzoic acid, chlorite, hypochlorite, sulfite, next sulfite, phosphorous acid, proton acid including hypophosphorous acid, and a mixture of two or more thereof. Also, examples of the alkali include sodium hydroxide, potassium hydroxide, calcium hydroxide, and a mixture of two or more thereof. The solvent is not particularly limited as long as an object of a present inventive subject matter is not interfered with, and the solvent may be an organic solvent that is different from the polar solvent and/or the nonpolar solvent, and may be an inorganic solvent such as water or may be a mixture of an organic solvent and an inorganic solvent. Examples of the organic solvent include an alcohol, an ester, and an ether. Examples of water include pure water, ultrapure water, tap water, well water, mineral spring water, mineral water, hot spring water, spring water, fresh water, and seawater.

The chemical composition to form an organic film is obtainable by mixing at least the raw material and the solvent. The method of mixing is not particularly limited, and may be a known mixing method may be used. For more details, the chemical composition is obtained by dissolving the organic compound into the solvent containing the nonpolar solvent and the polar solvent as an embodiment of a method of forming an organic film of a present inventive subject matter.

By use of the chemical composition of a present inventive subject matter, it is possible to form an organic film in enhanced quality even when an organic compound without a polar group is used. For more details, it is possible to form an organic film directly on a base or on at least one layer arranged on the base using the chemical composition as a raw material solution by methods to form atomized droplets according to a present inventive subject matter. Also, the chemical composition of the present inventive subject matter is preferably prepared as a raw-material solution that is to be turned into atomized droplets to form an organic film. Further preferably, the raw-material solution is turned into atomized droplets by use of ultrasonic vibration. The film-formation method is not particularly limited as long as an object of a present inventive subject matter is not interfered with, however, according to a method of an embodiment of a present inventive subject matter, a mist CVD method is preferably used. For more details, the method of forming an organic film of a present inventive subject matter includes preparing a raw material solution containing a solvent and an organic compound (Preparing a raw-material solution). The solvent of the raw material solution contains a nonpolar solvent and a polar solvent. The nonpolar solvent contains an aromatic compound. The polar solvent is an aprotic polar solvent. The method of forming the organic film of a present inventive subject matter further includes turning the raw material solution into atomized droplets (Forming atomized droplets from a raw-material solution), and carrying the atomized droplets onto the base (Carrying the atomized droplets onto a base); and causing thermal reaction of the atomized droplets adjacent to the base to form an organic film (Forming a film).

(Preparing a Raw-Material Solution)

The raw-material solution is not particularly limited as long as the raw-material solution contains a chemical composition for forming an organic film, and atomized droplets are able to be formed from the raw-material solution. According to an embodiment of a present inventive subject matter, the chemical composition itself may be used as a raw material solution.

The raw-material solution may contain an organic material and/or an inorganic material as long as an object of a present inventive subject matter is not interfered with. Also, the raw-material solution may contain the chemical composition and an additional material, which may contain an organic material and/or an inorganic material.

(Forming Atomized Droplets from a Raw Material Solution)

A raw material solution is turned into atomized droplets floating in a space of a container of a mist generator. The raw material solution may be turned into atomized droplets by a known method, however, according to an embodiment of a present inventive subject matter, the raw material solution is preferably turned into atomized droplets by use of ultrasonic vibration. Atomized droplets including mist particles, obtained by using ultrasonic vibration and floating in the space have the initial velocity that is zero. Since atomized droplets floating in the space are carriable as gas, the atomized droplets floating in the space are preferable to avoid damage caused by the collision energy without being blown like a spray. The size of droplets is not limited to a particular size, and may be a few mm, however, the size of droplets is preferably 50 μm or less. The size of droplets is further preferably in a range of 100 nm to 10 μm.

The raw material solution may contain an additional solvent in addition to the polar solvent and the nonpolar solvent. Such an additional solvent is not particularly limited as long as an object of a present inventive subject matter is not interfered with, and may be an organic solvent or an inorganic solvent except the polar solvent and the nonpolar solvent. Also, the additional solvent may be a mixed solvent of an organic solvent and an inorganic solvent. Examples of the organic solvent include an alcohol, an ester, and an ether. Also, the inorganic solvent may be water, for example. For more details, examples of water include pure water, ultrapure water, tap water, well water, mineral spring water, mineral water, hot spring water, spring water, fresh water, and seawater.

(Carrying the Atomized Droplets onto a Base)

Atomized droplets floating in the space of a container for forming atomized droplets are carried onto a base by carrier gas. The carrier gas is not particularly limited as long as an object of the present inventive subject matter is not interfered with, and thus, examples of the carrier gas include an oxidizing gas, an inert gas, and a reducing gas. Examples of the oxidizing gas include oxygen and ozone. Examples of the inert gas include nitrogen and argon. Also, examples of the reducing gas include a hydrogen gas and a forming gas. The type of carrier gas may be one or more, and a dilution gas at a reduced flow rate (e.g., 10-fold dilution gas) may be used further as a second carrier gas. The carrier gas may be supplied from one or more locations. The flow rate of the carrier gas is not particularly limited, however, the flow rate of the carrier gas may be in a range of 0.01 to 20 L/min. According to an embodiment of a present inventive subject matter, the flow rate of the carrier gas may be preferably in a range of 1 to 10 L/min. When a dilution gas is used, the flow rate of the dilution gas is preferably in a range of 0.001 to 2 L/min. According to an embodiment of a present inventive subject matter, when a dilution is used, the flow rate of the dilution gas is further preferably in a range of 0.1 to 1 L/min.

(Forming a film)

The atomized droplets carried onto the base by the carrier gas are thermally reacted (through “thermal reaction”) to form an organic film on the base. Herein, “thermal reaction” works as long as the atomized droplets react by heat, and conditions of reaction are not particularly limited as long as an object of a present inventive subject matter is not interfered with. According to embodiments of a present inventive subject matter, the thermal reaction is basically conducted at a temperature of 300° C. or less, and the thermal reaction is preferably conducted at a temperature of 210° C. or less. The lower limit of the temperature for thermal reaction is not particularly limited as long as an object of the present inventive subject matter is not interfered with, however, the temperature is preferably 100° C. or more, and further preferably 120° C. or more.

Also, the thermal reaction may be conducted in any environment such as in a vacuum environment, in a non-oxygen atmosphere, in a reducing-gas atmosphere, or in an oxygen atmosphere, however, the thermal reaction is preferably conducted in a non-oxygen atmosphere or in an oxygen atmosphere. Furthermore, the thermal reaction may be conducted under atmospheric pressure, under increased pressure or under decreased pressure, however, according to embodiments of a present inventive subject matter, the thermal reaction is preferably conducted under atmospheric pressure. The film thickness of the organic film to be obtained is easily adjusted by changing a film-formation time.

(Base)

The base is not particularly limited as long as the base is able to support a film to be directly or indirectly formed on the base. The material of the base (base material) is not particularly limited as long as an object of a present inventive subject matter is not interfered with, and the base may be a known base. Also, the base may contain an organic compound. Also, the base may contain an inorganic compound. Furthermore, the base may have a porous structure.

Also, a base including at least a layer formed on the base may be used as a base according to an embodiment of a method of a present inventive subject matter. Two or more layers may be arranged on the base. The layer may be partly arranged on the base. Also, the layer may be arranged on an entire surface of the base. Examples of the layer arranged on the base include a metal layer, a semiconductor layer, an electrically-conductive layer, and an electrically-insulating layer. Examples of a constituent material of the metal layer may contain one or more metals selected from among gallium, iron, indium, aluminum, vanadium, titanium, chromium, rhodium, nickel, cobalt, zinc, magnesium, calcium, silicon, yttrium, strontium, and barium. Examples of a constituent material of the semiconductor layer include a chemical element such as silicon or germanium, a chemical compound containing one or more chemical elements selected from among chemical elements of Group 3 to Group 5 in the periodic table and chemical elements of Group 13 to Group 15 in the periodic table. Examples of a constituent material of the metal oxide containing one or more chemical elements selected from among chemical elements of Group 3 to Group 5 in the periodic table and chemical elements of Group 13 to Group 15 in the periodic table, a metal sulfide containing one or more chemical elements selected from among chemical elements of Group 3 to Group 5 in the periodic table and chemical elements of Group 13 to Group 15 in the periodic table, a metal selenide containing one or more chemical elements selected from among chemical elements of Group 3 to Group 5 in the periodic table and chemical elements of Group 13 to Group 15 in the periodic table, and a metal nitride containing one or more chemical elements selected from among chemical elements of Group 3 to Group 5 in the periodic table and chemical elements of Group 13 to Group 15 in the periodic table. Examples of a constituent material of the electrically-conductive film include tin-doped indium oxide (ITO), fluorine-doped indium oxide (FTO), zinc oxide (ZnO), aluminum doped zinc oxide (AZO), gallium-doped zinc oxide (GZO), tin oxide (SnO₂), indium oxide (In₂O₃), and tungsten oxide (WO₃). According to an embodiment of the present invention, the electrically-conductive film including an electrically-conductive oxide is preferable, and further preferably is a tin-doped indium oxide (ITO) film. Examples of a constituent material of the electrically-insulating film include aluminum oxide (Al₂O₃), titanium oxide (TiO₂), silicon oxide (SiO₂), silicon nitride (Si₃N₄), silicon oxynitride (Si₄O₅N₃), and an electrically-insulating film made of an electrically-insulating oxide is preferable. The electrically-insulating film is further preferably a titania film, for example.

In forming the metal film, the semiconductor film, the electrically-conductive film, and/or the electrically-insulating film, the method of forming the metal film, the semiconductor film, the electrically-conductive film, and/or the electrically-insulating film is not particularly limited, and a known method may be used. Examples of the method of forming the metal film, the semiconductor film, the electrically-conductive film, and/or the electrically-insulating film include a mist CVD method, a sputtering method, a CVD (Chemical Vapor Deposition) method, an SPD (Spray Pyrolysis Deposition) method, an evaporation method, an ALD (Atomic Layer Deposition), and a coating method such as dipping, dropping, a doctor blade coating, ink jet coating, spin coating, brush coating, spray coating, roll coating, air knife coating, curtain coating, wire-bar coating, gravure coating, and inkjet coating.

Variously-shaped bases are available for a base. The base may have a plate shape, a circular plate shape, a shape of fiber, a shape of a stick, a shape of a round pillar, a shape of a square pillar, a shape of a tube, a shape of a spiral, a shape of sphere, and/or a shape of ring. According to an embodiment of a present inventive subject matter, the base may be an electrically-insulating substrate, a semiconductor substrate, a metal substrate, or an electrically-conductive substrate. According to an embodiment of a present inventive subject matter, the base is preferably a glass substrate.

According to an embodiment of a present inventive subject matter, the base preferably includes an electrically-conductive film on at least a part of a surface of the base. The base including an electrically-conductive film arranged entirely on the surface of the base is also preferable. The base that is a glass substrate and including an electrically-conductive film on at least a part of a surface of the base is further preferable. According to an embodiment of a present inventive subject matter, the base that is a glass substrate and including a tin-doped indium oxide film arranged on at least a part of a surface of the base is most preferable. The base that is a glass substrate and may include the tin-doped indium oxide film arranged entirely on the surface of the base.

According to an embodiment of a present inventive subject matter, an organic film may be formed directly on the base. Also, an organic film may be formed indirectly on the base, on which one or more layers may be formed, and the organic film may be formed on the one or more layers arranged on the base. Examples of the one or more layers include a buffer layer and/or a stress-relief layer. The buffer layer and/or the stress-relief layer may be formed by a known method, however, according to an embodiment of a present inventive subject matter, the buffer layer and/or the stress-relief layer are preferably formed by mist CVD apparatus.

Organic films that are formed as mentioned above are obtained in enhanced quality. Also, since the film thickness of the organic film is easily adjusted by changing a film-formation time, it is possible to form organic films industrially advantageously.

Organic films obtained according to embodiments of a present inventive subject matter may be formed as organic electrically-insulating films, organic semiconductor films, and electrically-conductive organic films. According to an embodiment of a present inventive subject matter, organic films may be preferably used for transistors and/or photoelectric conversion devices.

Embodiments are explained in more details.

### Practical Example 1

1. Film (Layer)-Formation Apparatus

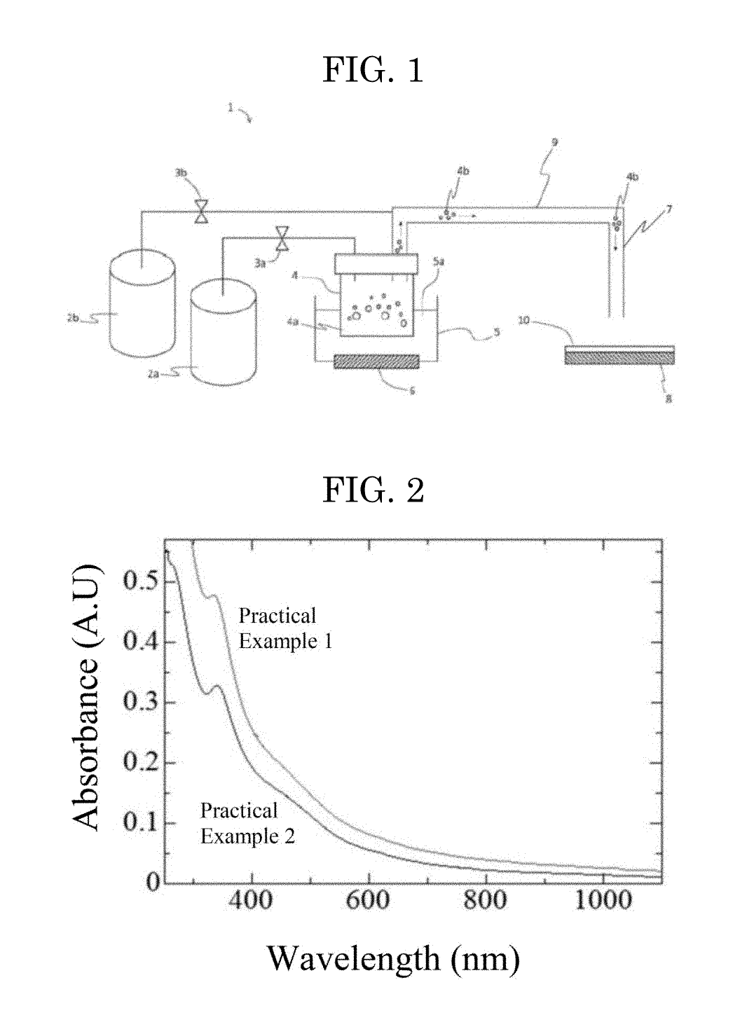

FIG. 1 shows a mist chemical vapor deposition (CVD) apparatus 1 used in practical examples and comparative examples to form an organic film (layer). The mist CVD apparatus 1 includes a carrier gas supply device 2a, a first flow-control valve 3a to control a flow of a carrier gas that is configured to be sent from the carrier gas supply device 2a, a diluted carrier gas supply device 2b, a second flow-control valve 3b to control a flow of a carrier gas that is configured to be sent from the diluted carrier gas supply device 2b, an atomized droplets (including mist) generator 4 in that a raw material solution 4a is contained, a vessel 5 in that water 5a is contained, and an ultrasonic transducer 6 that may be attached to a bottom surface of the vessel 5. The mist CVD apparatus 1 further includes a hot plate 8 on that a base 10 is placed. The mist CVD apparatus 1 further includes a supply tube 9 at a first end connected to the atomized droplets generator 4 to supply the atomized droplets carried by carrier gas onto the base 10 at a second end of the supply tube 9. The second end of the supply tube 9 may be positioned adjacent to the base 10 placed on the hot plate 8.

2. Preparation of Raw-Material Solution

A raw-material solution was prepared by mixing C60 fullerene into mesitylene (C60 fullerene as an organic compound has a solubility that is 1.5 mg/mL to mesitylene at the temperature of 25° C.) and 2-Pyrrolidone (C60 fullerene as an organic compound has a solubility that is approximately 0 mg/mL at the temperature of 25° C.). In the raw-material solution, the volume mixing ratio of mesitylene to 2-Pyrrolidone was 3:1, and the concentration of C60 fullerene in the raw-material solution was 1.4×10⁻³ mol/L.

3. Film (Layer) Formation Preparation

The raw-material solution 4a obtained at 2. the Preparation of the Raw-Material Solution above was set in the container of the atomized droplets generator 4. Also, a glass/ITO substrate (20 mm×25 mm) as a base 10 was placed on the hot plate 8. The hot plate 8 was activated to raise the temperature of the base 10 up to 210° C. The first flow-control valve 3a and the second flow-control valve 3b were opened to supply a carrier gas from the carrier gas device 2a and the diluted carrier gas device 2b. The flow rate of the carrier gas from the carrier gas source 2a was set at 2.0 L/min, and the diluted carrier gas from the diluted carrier gas source 22b was set at 4.0 L/min. In this embodiment, nitrogen was used as the carrier gas.

4. Formation of a Fullerene Film

The ultrasonic transducer 6 was then activated to vibrate at 2.4 MHz, and vibrations were propagated through the water 5a in the vessel 5 to the raw material solution 4a to turn the raw material solution 4a into atomized droplets 4b. The atomized droplets 4b were carried through a supply pipe 9 by the carrier gas onto the base 10, and the atomized droplets 4b heated and thermally reacted adjacent to the base 10 at 210° C. under atmospheric pressure to be a fullerene film on the base 10. The fullerene film obtained on the base 10 was approximately 50 nm in thickness.

5. Evaluation

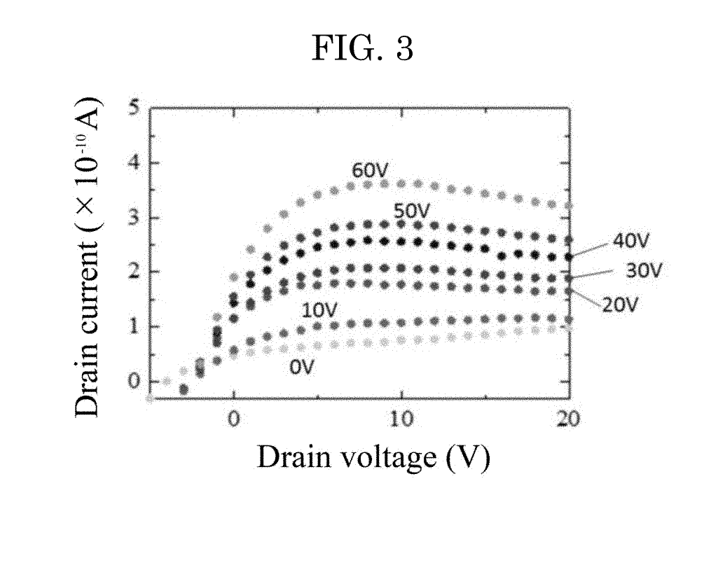

A UV-visible absorption measurement was conducted on the fullerene film obtained at 4. the Formation of a fullerene film above, and FIG. 2 shows the result. As shown in FIG. 2, the fullerene film had an absorption peak in a wavelength range of 300 nm to 400 nm. Also, transistor output characteristics of the fullerene film were measured, and FIG. 3 shows the result. As shown in FIG. 3, drain current of the fullerene film modulated in accordance with the increase of gate voltage from 0V to 60V, showing good characteristics as n-type semiconductor.

### Practical Example 2

As Practical Example 2, a fullerene film was obtained under the same conditions as the conditions in the Practical Example 1 except one condition that the atomized droplets heated and thermally reacted adjacent to the base at 180° C. to be a fullerene film on the base. A UV-visible absorption measurement was conducted on the fullerene film obtained here at Practical Example 2, and FIG. 2 shows the result. As shown in FIG. 2, the fullerene film obtained at Practical Example 2 had an absorption peak in a wavelength range of 300 nm to 400 nm.

### Practical Example 3 and Practical Example 4

As Practical Example 3, a fullerene film was obtained under the same conditions as the conditions in the Practical Example 1 except one condition that the atomized droplets heated and thermally reacted adjacent to the base at 150° C. to be a fullerene film on the base. A UV-visible absorption measurement was conducted on the fullerene film obtained here at Practical Example 3, and the fullerene film had an absorption peak in a wavelength range of 300 nm to 400 nm.

As Practical Example 4, a fullerene film was obtained under the same conditions as the conditions in the Practical Example 1 except one condition that the atomized droplets heated and thermally reacted adjacent to the base at 120° C. to be a fullerene film on the base. A UV-visible absorption measurement was conducted on the fullerene film obtained here at Practical Example 4, and the fullerene film had an absorption peak in a wavelength range of 300 nm to 400 nm.

### Practical Example 5, Practical Example 6, Practical Example 7, and Practical Example 8

As Practical Example 5, a fullerene film was obtained under the same conditions as the conditions in the Practical Example 1 except one condition that the volume mixing ratio of mesitylene to 2-Pyrrolidone was 4:1. A UV-visible absorption measurement was conducted on the fullerene film obtained here at Practical Example 5, and the fullerene film had an absorption peak in a wavelength range of 300 nm to 400 nm.

As Practical Example 6, a fullerene film was obtained under the same conditions as the conditions in the Practical Example 2 except one condition that the volume mixing ratio of mesitylene to 2-Pyrrolidone was 4:1. A UV-visible absorption measurement was conducted on the fullerene film obtained here at Practical Example 6, and the fullerene film had an absorption peak in a wavelength range of 300 nm to 400 nm.

As Practical Example 7, a fullerene film was obtained under the same conditions as the conditions in the Practical Example 3 except one condition that the volume mixing ratio of mesitylene to 2-Pyrrolidone was 4:1. A UV-visible absorption measurement was conducted on the fullerene film obtained here at Practical Example 7, and the fullerene film had an absorption peak in a wavelength range of 300 nm to 400 nm.

As Practical Example 8, a fullerene film was obtained under the same conditions as the conditions in the Practical Example 4 except one condition that the volume mixing ratio of mesitylene to 2-Pyrrolidone was 4:1. A UV-visible absorption measurement was conducted on the fullerene film obtained here at Practical Example 8, and the fullerene film had an absorption peak in a wavelength range of 300 nm to 400 nm.

### Practical Example 9, Practical Example 10, Practical Example 11, and Practical Example 12

As Practical Example 9, a fullerene film was obtained under the same conditions as the conditions in the Practical Example 1 except one condition that the volume mixing ratio of mesitylene to 2-Pyrrolidone was 7:3. A UV-visible absorption measurement was conducted on the fullerene film obtained here at Practical Example 9, and the fullerene film had an absorption peak in a wavelength range of 300 nm to 400 nm.

As Practical Example 10, a fullerene film was obtained under the same conditions as the conditions in the Practical Example 2 except one condition that the volume mixing ratio of mesitylene to 2-Pyrrolidone was 7:3. A UV-visible absorption measurement was conducted on the fullerene film obtained here at Practical Example 10, and the fullerene film had an absorption peak in a wavelength range of 300 nm to 400 nm.

As Practical Example 11, a fullerene film was obtained under the same conditions as the conditions in the Practical Example 3 except one condition that the volume mixing ratio of mesitylene to 2-Pyrrolidone was 7:3. A UV-visible absorption measurement was conducted on the fullerene film obtained here at Practical Example 11, and the fullerene film had an absorption peak in a wavelength range of 300 nm to 400 nm.

As Practical Example 12, a fullerene film was obtained under the same conditions as the conditions in the Practical Example 4 except one condition that the volume mixing ratio of mesitylene to 2-Pyrrolidone was 7:3. A UV-visible absorption measurement was conducted on the fullerene film obtained here at Practical Example 12, and the fullerene film had an absorption peak in a wavelength range of 300 nm to 400 nm.

### Comparative Example 1

As Comparative Example 1, film-formation was conducted under the same conditions as the conditions in Practical Example 1 except one condition that the volume mixing ratio of mesitylene to 2-Pyrrolidone was 10:1. As a result, the film obtained here at Comparative Example 1 was insufficient in film quality and film-formation speed was 1/10 or slower than the film-formation speed of Practical Example 1.

### Comparative Example 2

As Comparative Example 2, film-formation was conducted under the same conditions as the conditions in Practical Example 1 except one condition that the volume mixing ratio of mesitylene to 2-Pyrrolidone was 2:3. As a result, atomized droplets were not sufficiently generated and a film was not formed on the base.

### Comparative Example 3

As Comparative Example 3, film-formation was conducted under the same conditions as the conditions in Practical Example 1 except one condition that only mesitylene was used as the solvent. As a result, a film was not sufficiently formed on the base and the film adhesion to the base was not good. Also, film-formation speed was 1/10 or slower than the film-formation speed of Practical Example 1.

### Comparative Example 4

As Comparative Example 4, film-formation was conducted under the same conditions as the conditions in Practical Example 1 except one condition that only 2-Pyrrolidone was used as the solvent. However, C60 fullerene was hardly dissolved into the solvent. Furthermore, it was difficult to generate atomized droplets of the raw-material solution, and a film was not formed on the base.

Using a solvent in a raw material solution according to embodiments of a present inventive subject matter, it is possible to form an organic film in good quality easily. In particular, since it is possible to form an organic film on a base at a low temperature and under atmospheric pressure without a vacuum system, bases of various materials are available. Also, organic films obtained according to a present inventive subject matter are able to be used in various fields.

Furthermore, while certain embodiments of the present inventive subject matter have been illustrated with reference to specific combinations of elements, various other combinations may also be provided without departing from the teachings of the present inventive subject matter. Thus, the present inventive subject matter should not be construed as being limited to the particular exemplary embodiments described herein and illustrated in the Figures, but may also encompass combinations of elements of the various illustrated embodiments.

Many alterations and modifications may be made by those having ordinary skill in the art, given the benefit of the present disclosure, without departing from the spirit and scope of the inventive subject matter. Therefore, it must be understood that the illustrated embodiments have been set forth only for the purposes of example, and that it should not be taken as limiting the inventive subject matter as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the inventive subject matter.

### REFERENCE NUMBER DESCRIPTION

1 a film (layer)-formation apparatus
2a a carrier gas supply device
2b a diluted carrier gas supply device
3a a flow-control valve of carrier gas
3b a flow-control valve of diluted carrier gas
4 a generator of atomized droplets
4a a raw material solution
4b an atomized droplet
5 a vessel
5a water
6 an ultrasonic transducer
8 a hot plate
9 a supply tube
10 a base

What is claimed is:

1. A solvent comprising:
a nonpolar solvent comprising an aromatic compound; and
a polar solvent that is an aprotic polar solvent,
the ratio of the nonpolar solvent to the polar solvent by volume ratio being 5:1 to 1:1.

2. The solvent of claim 1, wherein
the aromatic compound comprised in the nonpolar solvent is represented by Chemical Formula (1), 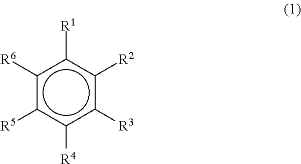
in the Chemical Formula (1), wherein
R¹, R², R³, R⁴, R⁵ and R⁶ each represent a hydrogen atom or an optionally substituted hydrocarbon group.

3. The solvent of claim 2, wherein
two selected from among R¹, R², R³, R⁴, R⁵ and R⁶ in the Chemical Formula (1) are taken together to form a ring.

4. The solvent of claim 1, wherein
the aprotic polar solvent is an amide solvent.

5. The solvent of claim 1, wherein
the polar solvent has a boiling point that is higher than a boiling point of the nonpolar solvent by 50° C. or higher.

6. The solvent of claim 1, wherein
the ratio of the nonpolar solvent to the polar solvent by volume ratio is 4:1 to 7:3.

7. A chemical composition comprising:
the solvent of claim 1; and
an organic compound.

8. The chemical composition of claim 7, wherein
the organic compound is a cyclic compound.

9. The chemical composition of claim 7, wherein
the organic compound is without a polar group.

10. The chemical composition of claim 7, wherein
the organic compound has a solubility that is less than 1.0 mg/mL to the polar solvent at a temperature of 25° C.

11. A solvent comprising:
a nonpolar solvent comprises an aromatic compound; and
a polar solvent that is an aprotic polar solvent,
the ratio of the nonpolar solvent to the polar solvent by volume ratio being 4:1 to 7:3.

12. The solvent of claim 11, wherein
the aromatic compound comprised in the nonpolar solvent is represented by Chemical Formula (1), 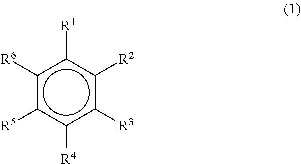
in the Chemical Formula (1), wherein
R¹, R², R³, R⁴, R⁵ and R⁶ each represent a hydrogen atom or an optionally substituted hydrocarbon group.

13. The solvent of claim 12, wherein
two selected from among R¹, R², R³, R⁴, R⁵ and R⁶ in the Chemical Formula (1) are taken together to form a ring.

14. The solvent of claim 11, wherein
the aprotic polar solvent is an amide solvent.

15. The solvent of claim 11, wherein
the polar solvent has a boiling point that is higher than a boiling point of the nonpolar solvent by 50° C. or higher.

16. A chemical composition comprising:
the solvent of claim 11; and
an organic compound.

17. The chemical composition of claim 16, wherein
the organic compound is a cyclic compound.

18. The chemical composition of claim 16, wherein
the organic compound is without a polar group.

19. The chemical composition of claim 16, wherein
the organic compound has a solubility that is less than 1.0 mg/mL to the polar solvent at a temperature of 25° C.

20. A method of forming an organic film comprising:
preparing a raw material solution comprising a solvent and an organic compound, the solvent comprising a nonpolar solvent that comprises an aromatic compound and a polar solvent that is an aprotic polar solvent;
turning the raw material solution into atomized droplets;
carrying the atomized droplets onto the base; and
causing thermal reaction of the atomized droplets adjacent to the base to form an organic film.

21. The method of claim 20, wherein
the turning the raw material solution into atomized droplets is done by using ultrasonic vibration.

22. The method of claim 20, wherein
the base comprises at least one layer.
